(19) United States
(12) Patent Application Publication
(10) Pub. No.: US 2007/0178615 A1
(43) Pub. Date: Aug. 2, 2007

(54) Semiconductor nanocrystal-based optical devices and method of preparing such devices

(75) Inventors: Uri Banin, Mevasseret Zion (IL); Miri Kazes, Ramia (IL); David Y. Lewis, Jerusalem (IL)

Correspondence Address: BROWDY AND NEIMARK, P.L.L.C.;624 NINTH STREET, NW, SUITE 300, WASHINGTON, DC, 20001-5303, US

(73) Assignee: Yissum Research Development Company of the Hebrew University of Jerusalem, Jerusalem (IL)

(21) Appl. No.: 10/557,490

(22) PCT Filed: May 20, 2004
(86) PCT No.: PCT/IL04/00432

§ 371 Date: Oct. 17, 2006

Related U.S. Application Data
(60) Provisional application No. 60/472,141, filed on May 21, 2003.

(51) Int. Cl. H01L 21/00; H01S 5/00; H01S 3/04

(52) U.S. Cl. 438/29; 372/43.01

(57) ABSTRACT

A method and optical device produced by such method are presented. The method consists of processing a structure formed by a nanocrystals solution on a surface of a substrate, to thereby produce a film of said nanocrystals on said surface, and create within an interface between said film and said surface, a region capable of operating as an active region of the optical device. Preferably, the film is created by applying electromagnetic radiation, such as laser radiation, to said structure.

### FIELD OF THE INVENTION

This invention relates to a semiconductor optical device and, more particularly, to a semiconductor optical device suitable for use as a laser.

### LIST OF REFERENCES

The following references are considered to be pertinent for the purpose of understanding the background of the present invention:
1. V. I. Klimov, A. A. Mikhailovsky, D. W. McBranch, C. A. Leatherdale, M. G. Bawendi, Science, 287:1011, 2000.
2. M. Kazes, D. Y. Lewis, Y. Ebenstein, T. Mokari, U. Banin, Adv. Mater., 14:317, 2002.
3. H. J. Eisler, V. C. Sundar, M. G. Bawendi, M. Walsh and H. I. Smith, Appl. Phys. Lett., 80:4614, 2002.
4. X. G. Peng, L. Manna, W. D. Yang, J. Wickham, A. Kadavanich, and A. P. Alivisatos, Nature, 404:59, 2000.
5. S. H. Kan, T. Mokari, E. Rothenberg and U. Banin, Nature Mater., 2:155, 2003.
6. A. V. Malko, A. A. Mikhailovsky, M. A. Petruska, et al., Appl. Physd. Lett., 81:1303, 2002.
7. B. Moller, M. V. Artemyev, U. Woggon, and R. Wannemacher, Appl. Phys. Lett., 80:3253, 2002.
8. L. Manna, E. C. Scher, A. P. Alivisatos, J. Am. Chem. Soc., 22, 12700, 2000.
9. Z. A. Peng, X. Peng, J. Am. Chem. Soc., 123:1389, 2001.
10. C. B. Murray, D. J. Norris and M. G. Bawendi, J. Am. Chem. Soc., 115, 8706.1993.
11. Y. W. Cao and U. Banin, J. Am. Chem. Soc., 122, 9692, 2000.
12. L. Manna, D. J. Milliron, A. Meisel, E. C. Scher, A. P. Alivisatos, Nat. Mat. 2, 382, 2003.
13. T. Mokari, U. Banin, Chem. Mater. 15, 3955, 2003.

The above references will be acknowledged in the text below by indicating their numbers [in brackets] from the above list.

### BACKGROUND OF THE INVENTION

Semiconductor nanocrystals provide extremely broad spectral coverage for luminescence through size and shape control via the quantum confinement effect. This property is an obvious advantage for their usage as the active media in optical amplification devices. Optical gain was measured for spherical CdSe nanocrystals in close-packed films [1], and optically pumped lasing was observed for nanocrystals in solution [2] and in nanocrystal-titania films on a grating structure that provided a distributed feedback cavity [3].

In a previous study [2], lasing in quantum rod solutions within a cylindrical microcavity was observed, and it was found that the threshold for lasing of a rod sample is lower in comparison with spherical dots. The reduction in threshold was assigned to several factors including increased absorption cross-section in rods, reduction of the Auger rates, and reduced reabsorption on account of the larger absorption—emission stokes shift in rods as compared to dots. Additionally, the existence of axial symmetry in rods leads to polarized emission that has also yielded polarized lasing, while for dots the lasing in a similar configuration was unpolarized.

Optical gain is of particular advantage in nanocrystals. Rod-shaped nanocrystals are also termed in the literature “quantum rods” or “nanorods”. Methods for the synthesis of quantum rods of II-VI and III-V semiconductors have been recently developed [4, 5]. Methods for the synthesis of nanocrystals of other shapes such as spheres [10, 11], tetrapods [12], etc. are also described in the literature.

Lasing was also reported for spherical CdSe nanocrystals that were deposited as solid films from hexane solution into capillaries [6], and nanocrystals have also been placed in spherical polymer microcavities that modulated the allowed emission bands [7].

### SUMMARY OF THE INVENTION

The present invention provides a method for preparing lasing nanocrystal films using processing a nanocrystals solution for preparing a nanocrystals film, which is particularly useful in preparing optical devices, such as lasers, amplifiers, sensors, etc.

In a preferred embodiment of the invention, the method comprises applying electromagnetic radiation (e.g., laser radiation) to a surface that holds a nanocrystals solution in order to evaporate the solution's solvent and form a lasing film on that surface. An interface between the surface and the so-prepared film serves as the active region of an optical device.

Examples of surfaces that may be used in the method of the invention are: the inner surface of a cylindrical microcavity, a waveguide or optical cavity structure on a chip, or a substantially planar surface. The laser irradiation evaporates the solvent of the nanocrystals solution while at the same time creates an annealed nanocrystal film with advantageous lasing properties. The films prepared by the method of the invention demonstrate properties such as stable and intense lasing at room temperature, which make them suitable for use in nanocrystal-based optical gain devices.

Considering as a specific example the inner surface of a cylindrical microcavity, the lasing film is formed by first loading the cylindrical microcavity, such as a glass capillary, with a concentrated solution of the nanocrystals, e.g. nanorods, and then irradiating the cavity with an intense laser. Heat created by the laser beam evaporates the solvent leaving a dense nanocrystals film on the inner walls of the capillary. This is a new method for preparation of nanocrystal films. The resulting film is then used in the production of an optical device.

According to another embodiment of the invention, the nanocrystals film may be prepared by exposing a substantially planar surface, holding the nanocrystals solution, to known coating techniques such as dip or spin coating. The resulting film is then used in the production of an optical device by irradiating it with intense electromagnetic radiation (e.g. laser).

The method of the invention is carried out with nanocrystal solutions of semiconductor materials. The nanocrystals may have the shape of nanospheres, nanorods, branched structures such as tripods and tetrapods, tubes and wires.

Preferably, the nanocrystals are nanorods having a rod-like shape.

The term “nanorod” is meant to describe a nanoparticle with extended growth along the first axis while maintaining very small dimensions along the other two axes, resulting in the growth of a rod-like shaped nanocrystal of a very small diameter, in the range of about 1 nm to about 100 nm, where the dimensions along the first axis may range from about several nanometers to about 1 micrometer. The terms “nanorod” and “quantum rod” are used interchangeably in the present specification.

Preferably, the nanocrystals (e.g., nanorods) are made of a semiconductor material selected from Group II-VI semiconductors, such as for example CdS, CdSe, CdTe, ZnS, ZnSe, ZnO and alloys (e.g. CdZnSe); Group III-V semiconductors such as InAs, InP, GaAs, GaP, InN, GaN, InSb, GaSb and alloys (e.g., InAsP); Group IV-VI semiconductors such as PbSe and PbS and alloys; and Group IV semiconductors such as Si and Ge and alloys. Additionally, combinations of the above in composite structures consisting of sections with different semiconductor materials, for example CdSe/CdS or any other combinations, as well as core/shell structures of different semiconductors such as for example CdSe/ZnS core/shell nanorods [13], are also within the scope of the present invention.

There is thus provided according to one aspect of the invention, a method of producing a nanocrystals film for use in a solid state nanocrystal-based optical device, the method comprising processing a structure formed by a nanocrystals solution on a surface of a substrate, to thereby produce a film of said nanocrystals on said surface, and create within an interface between said film and said surface a region capable of operating as an active region of the optical device. The term “active region” is meant to denote a region which is capable of producing optical radiation by the process of stimulated emission.

According to another aspect of the invention, there is provided a method of producing a nanocrystals film for use in a solid state nanocrystals-based optical device, the method comprising applying electromagnetic radiation to a nanocrystals solution on a surface of a substrate, thereby producing a film of said nanocrystals on said surface, and creating within an interface between said film and said surface, a region capable of operating as an active region of the optical device.

The electromagnetic radiation is preferably laser radiation, which may be continuous wave (CW) radiation or pulsed radiation. The substrate's surface may be substantially planar. Alternatively, this may be an inner surface of a substantially cylindrically or spherically shaped substrate. The substrate may be a waveguide or optical cavity structure on a chip.

Preferably, a sequence of high-energy laser pulses is used for irradiating a nanocrystals solution on the substrate's surface (e.g., contained in a micro-cavity), in a rate ranging from kHz to Hz, preferably in the range of 1 Hz to 1 kHz, more preferable in the range of 1-30 Hz. The irradiation is continued until a solidified film is formed around the irradiated spot.

According to yet another aspect of the present invention, there is provided an optical device, comprising a nanocrystals film on a surface of a substrate, an active region of said device being presented by an interface between said film and said surface, said active region being created by processing a solution of said nanaocrystals while on said surface to thereby produce said film.

More specifically, the present invention is useful for producing a laser device and is therefore described below with reference to this application.

### BRIEF DESCRIPTION OF THE DRAWINGS

In order to understand the invention and to see how it may be carried out in practice, preferred embodiments will now be described, by way of non-limiting example only, with reference to the accompanying drawings, in which:

FIG. 1 schematically illustrates the principles of a laser induced film preparation method of the present invention for producing lasing films of semiconductor nanorods.

FIG. 2 shows a build-up process for lasing of quantum rods (4×14 nm) in the capillary tube.

FIG. 3A is a graph showing the lasing in CdSe/ZnS core/shell structured quantum rods, 4 nm in diameter and 24 nm in length, at different pump powers of: 0.01 mJ, 0.02 mJ, 0.4 mJ, 0.55 mJ, 0.8 mJ.

FIG. 3B is a graph showing the intensity of the lasing peak (filled squares) and the fluorescence (empty circles) vs. the pump power.

FIG. 4A shows a photograph of a solidified film of CdSe/ZnS quantum rods in a glass capillary under a fluorescence optical microscope.

FIG. 4B shows a Scanning Electron Microscope (SEM) image of the free standing portion of the film exposed at the edge of the capillary showing the formation of a densely packed solidified film.

FIGS. 5A and 5B show Energy Depressive X-ray Spectroscopy (EDS) under a Scanning Electron Microscope, wherein FIG. 5A corresponds to an exposed portion of a film showing the existence of Cd, Se, Zn and S which are the elements that the quantum rods are composed of, in addition to organic material, mainly P, from the trioctylphosphine oxide (TOPO) and the phosphonic acids which is the ligands coating the rods; and FIG. 5B shows EDS of the glass capillary taken as a reference.

FIG. 6 shows Transmission Electron Microscope (TEM) image of a redissolved film of 4×24 mn CdSs/ZnS quantum rods.

FIGS. 7A to 7C show high-resolution lasing spectra of the quantum rods in cylindrical microcavities of varied diameters exhibiting corresponding whispering gallery modes (WGM's) lasing peaks: FIG. 7A shows the spectrum from a capillary of 200 micron inner diameter, FIG. 7B shows the spectrum from a capillary of 153 micron inner diameter, and FIG. 7C shows the lasing spectrum in a different configuration where an optical fiber with a 125 micron diameter acts as the cavity. Inset: Plot of the spacing of the modes versus mode serial number, where the slope gives an average spacing of 0.32, 0.5 and 0.62 nm for the 125 micron fiber, the 150 micron capillary and the 200 micron capillary, respectively.

FIG. 8 shows a stability measurement of lasing in a pre-prepared film. The shot number is indicated on each trace (traces were vertically offset for clarity of presentation). Inset: A low resolution spectra of the nanorod photoluminescence (dashed line) and lasing (solid line).

FIG. 9A shows the emission spectra of quantum rods of 4.8 nm in diameter and 15 nm in length at different excitation stripe length. From bottom-up: 0.05 cm, 0.08 cm, 0.1 cm and 0.14 cm. The emission spectra shows narrowing as the stripe length is increased. The inset shows the emission spectra in linear scale where the stripe length for the first three traces as in the main figure and the dotted line is for a stripe length of 0.14 cm and the intensity is divided by 18, to clearly show the significant narrowing for optical gain in the films.

FIG. 9B shows a plot of the ASE intensity at the emission peak versus the stripe length in linear scale. The theoretical fit gives a gain factor of 97 cm⁻¹. The inset displays schematically the experimental configuration in which an excitation laser beam is focused into a stripe on a planar film. The stripe length is adjusted by a moveable barrier while the spectrum is measured at each length.

### DETAILED DESCRIPTION OF THE INVENTION

The present invention provides a solid state nanocrystals-based optical device and a method for producing such a device. Generally, the inventors have developed a technique of preparing lasing films from semiconductor nanocrystals. According to the preferred embodiment of the invention, this is achieved by processing a nanocrystals solution carried by a surface of a substrate with electromagnetic radiation.

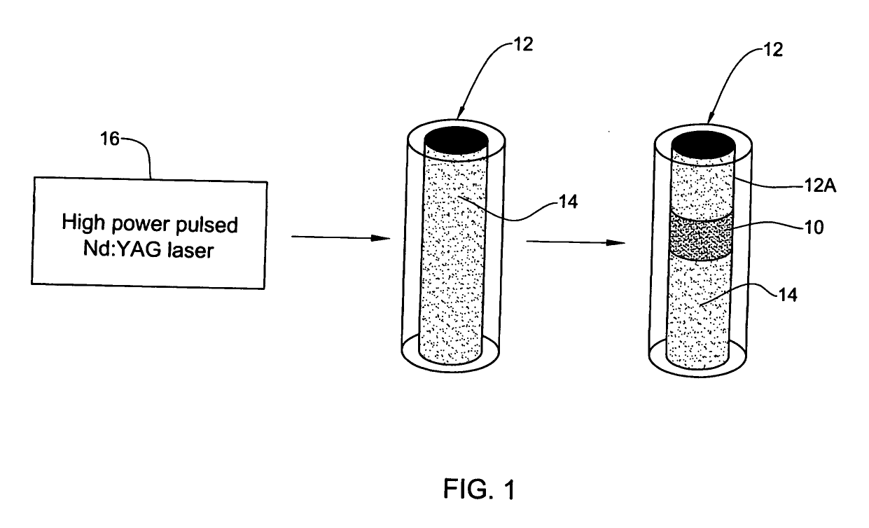

In one particular and non-limiting example of the method of the invention, as shown in FIG. 1, an optical device (e.g., laser cavity) is formed by a film 10 of nanorods on the surface 12A of a substrate 12, which is in the form of a glass capillary. An active region of the so-formed optical device is defmed by an interface between the film and the substrate's surface.

The film 10 is formed by first loading the glass capillary 12 with a concentrated solution 14 of the quantum rods, and then irradiating the capillary 12 with predetermined laser radiation produced by an intense laser 16. In the present example, a sequence of intense laser pulses is used. Heat created by the laser beam evaporates the solvent leaving a dense nanorod film on the inner walls of the capillary.

In this particular example, lasing films were prepared from semiconductor nanorods. The quantum rods were grown using the methods of colloidal nanocrystal synthesis utilizing high temperature pyrolysis of organometallic precursors in coordinating solvents [8, 9], and were overcoated by hexadecylamine (HDA) and trioctylphosphine oxide (TOPO). The core/shell configuration for the rods was used since the growth of a few monolayers of ZnS on the organically coated CdSe quantum rods enhances the fluorescence quantum yield from about 1% to 20% [13]. The shell, composed of ZnS that has a band gap enclosing that of CdSe, passivates potential surface traps that in the organically coated CdSe rods provide efficient non-radiative decay routes for the excited charge carriers, and therefore enables more easily the achievement of population inversion required for lasing.

Capillary tubes with a diameter of 200 microns were loaded with concentrated solutions of CdSe/ZnS rods in toluene within a glove box, and sealed by epoxy glue. The concentration of the nanocrystals in solutions was about 1.4×10⁻⁵ M. The capillary tubes were then irradiated from the side using the second harmonic of a Nd-YAG laser at 532 nm (beam radius w˜0.3 mm), to prepare solid-state nanocrystals films as described below. The emission was monitored by collecting it at 90 degrees and detected using a spectrograph/CCD setup. All experiments were carried out in ambient conditions.

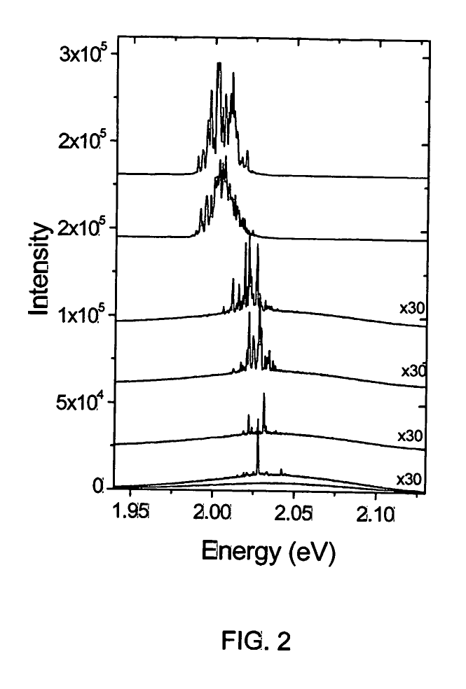

The preparation of robust lasing films within the capillary tube entails using laser irradiation to evaporate the solvent and leave behind an annealed lasing film. FIG. 2 shows a typical build-up process of stable lasing, in this case demonstrated for a rod sample with dimensions of 4×14 nm. The capillary was illuminated by a sequence of pump pulses with intensity of about 3 mJ at 5 Hz. Shot numbers for the shown traces in sequential order from down-up are: 110, 112, 113, 114, 135, 240 and 242 shots. At first, only the fluorescence is detected. But after approximately 110 shots at 3 mJ pump power, WGM lasing is starting to develop and a lasing peak emerges, which the initial intensity is weak at first, and then increases with additional pump laser shots. Such a pre-prepared area then yields robust lasing and shows the low threshold behavior (the lower spectra are multiplied by a factor of 30). Following the film preparation method described here, a lasing peak at 2 eV appeared above a threshold of 0.02 mJ.

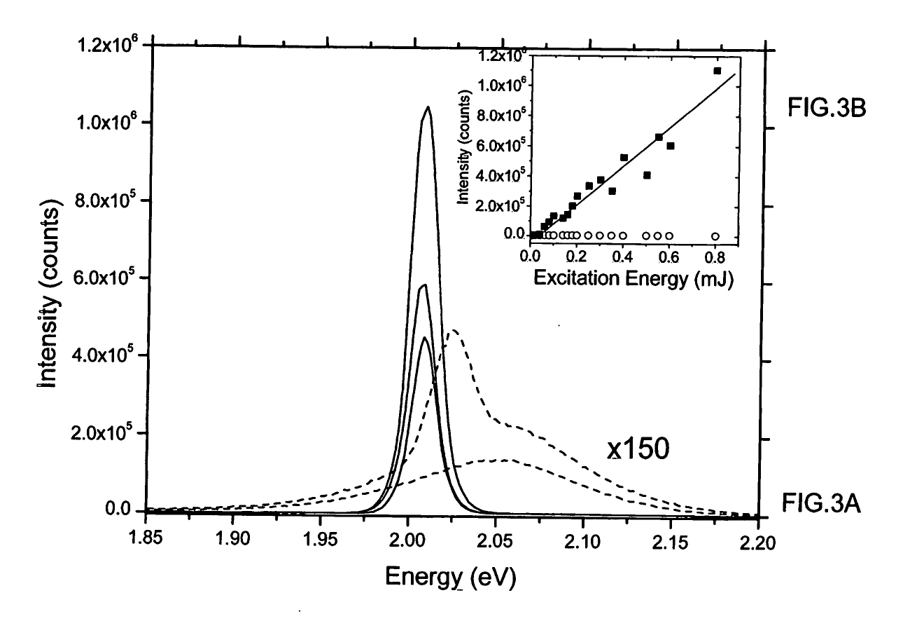

FIG. 3A presents the results of lasing for CdSe/ZnS quantum rods with size 4×24 (diameter×length) within the capillary tube, at different pump powers, after the preparation process similar to the one detailed above. The pump intensities from low to high are as follows: 0.01 mJ, 0.02 mJ, 0.4 mJ, 0.55 mJ and 0.8 mJ. The use of another rod size serves to directly demonstrate the versatility of the method to different rods and other nanocrystals. The dependence of the intensity of the lasing (dark squares) and fluorescence (empty circles) on pump power is shown in FIG. 3B, for several laser excitation intensities where each spectrum corresponds to a single laser shot. At intensities starting around 0.02 mJ, a narrow lasing peak clearly emerges, to the red of the fluorescence peak. At higher intensities, the lasing peak shifts further to the red spectrum and completely dominates the emission exhibiting intensities that are nearly three orders of magnitude larger than the saturated fluorescence intensity. The lasing shows clear threshold behavior manifested as an abrupt change of slope at the onset of laser action, while at the same time, the peak fluorescence intensity is saturated.

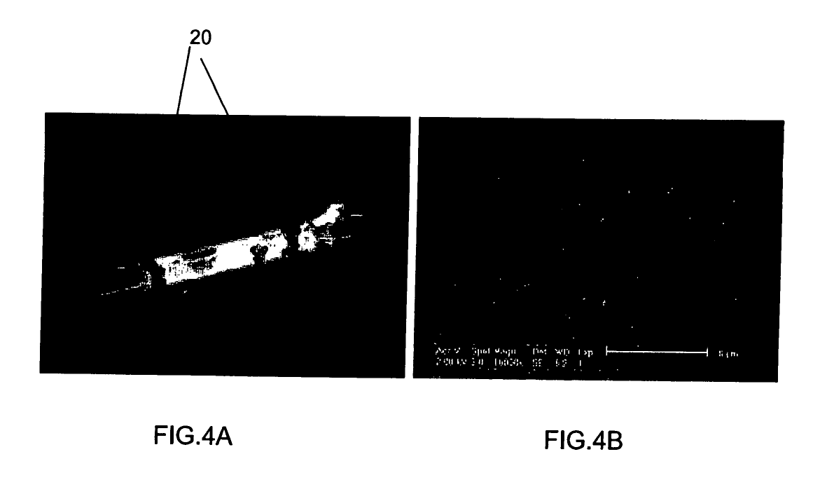

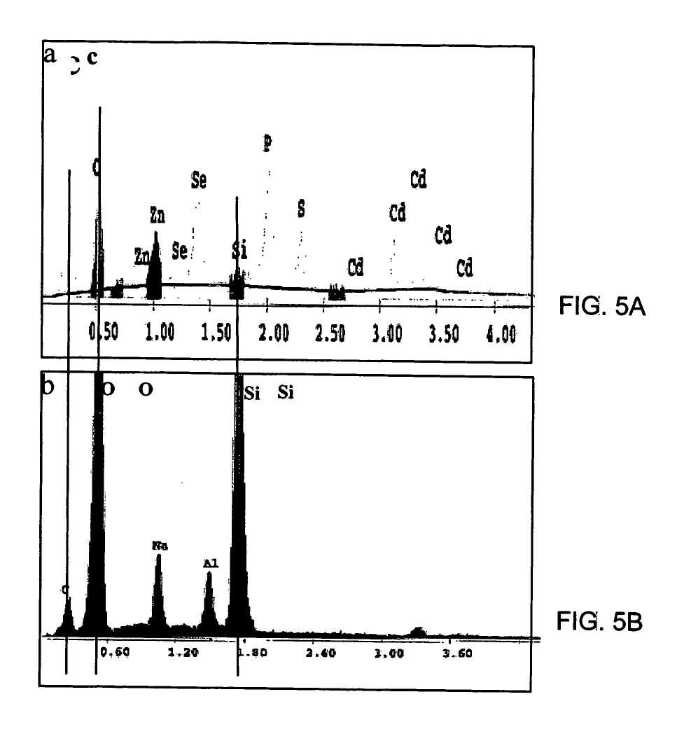

Several characterization methods were preformed in order to analyze and verify the nature of the pre-prepared lasing films. FIG. 4A shows a photograph of a solidified film of CdSe/ZnS quantum rods in a glass capillary under a fluorescence optical microscope. The quantum rods fluorescence (regions 20 in FIG. 4A) indicates the areas where the lasing film was created. Scanning Electron Microscope (SEM) measurement was performed on the free-standing portion of the film seen at the edge of the capillary, exposed by intentionally breaking the capillary for analysis. The SEM image shown in FIG. 4B reveals a densely packed film. Energy dispersive X-ray spectroscopy (EDS) showed Cd and Se corresponding to the core, Zn and S corresponding to the shell, and P from the organic ligand layer on the outer shell surface (FIG. 5A). A reference measurement taken on the glass capillary showed the expected Si and traces of Al and Na impurities of the glass (FIG. 5B).

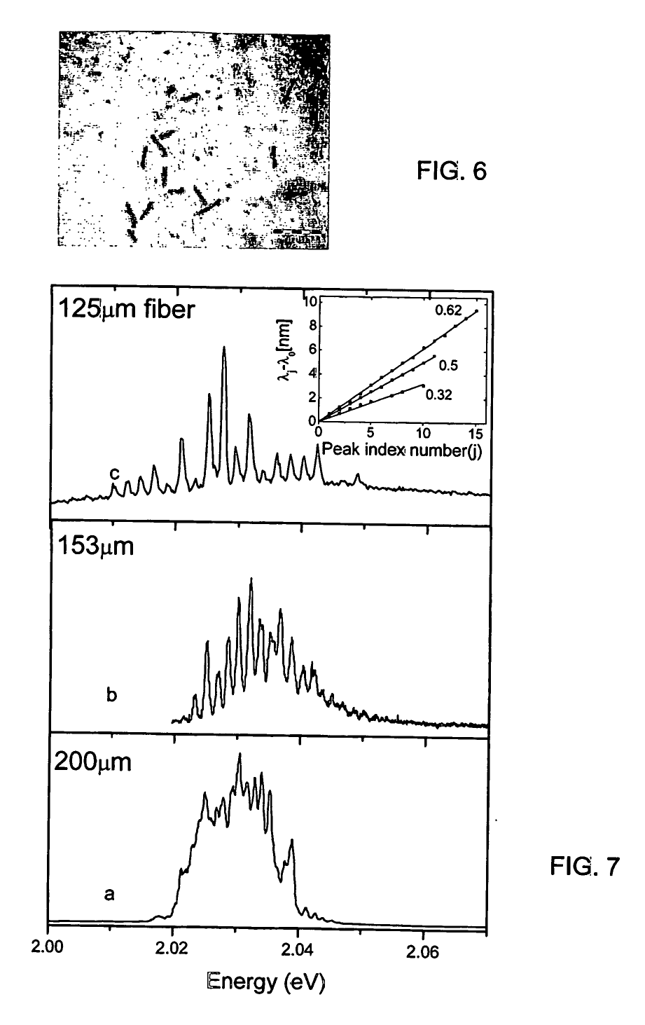

In order to verify that there is no structural damage done to the nanorods by the film preparation process, TEM images were taken for the rods after such a process. Redissolving parts of the quantum rods film in toluene by vigorous sonication and dispersing them onto the grid showed that the basic rod shape is maintained following the laser preparation step (FIG. 6). This is also corroborated by the fluorescence spectrum of the quantum rod film, which maintains the spectral signature of the rods.

This preparation method was found very reproducible in achieving efficient lasing and was measured for CdSe/ZnS quantum rods of different dimensions, for example 4 nm×14 nm, 4 nm×24 nm, rods of 3×11 nm and of 6×30 nm, and also demonstrated for CdSe/ZnS quantum dots. The method can be employed to create lasing and optical gain producing nanorod films in diverse geometries including on chip architectures.

Further information on the type of lasing modes that are observed, in particular to distinguish between whispering gallery modes (WGMs) and radial modes, was provided by high resolution spectra taken using the second order diffraction from the spectrometer grating. FIGS. 7A-7C show three such spectra for the 200 micron capillary (FIG. 7A), for a 153 micron capillary (FIG. 7B), and for a different case where an optical fiber with a 125 micron diameter is inserted within a 200 micron capillary (FIG. 7C), i.e., the fiber surface acts as the cavity and the rods in solution acts as the lasing media. All three spectra show a peak structure corresponding to WGMs that are best resolved for the cavity with the smallest diameter and hence largest spacing. The average spacing, Δλ, was extracted as the slope of the linear plots (inset of FIG. 7C), showing the wavelength difference between the first discernible peak, and the next peaks indexed in consecutive manner. This is the plot of the spacing of the modes versus mode serial number, where the slope gives an average spacing of 0.32, 0.5, and 0.62 nm for the 200 micron capillary, the 153 micron capillary and the 125 micron fiber, respectively.

For WGMs, Δλ˜λₙ²/(m₂2 πr), wherein m₂ is the refractive index at the lasing interface and λₙ is the detected mode wavelength. There are effectively two free parameters—namely the actual radius of the WGMs and the refractive index. Starting with the fiber (FIG. 7C), and assuming that the lasing occurs on the fiber surface, a refractive index value of 1.54±0.05 was obtained, close to the refractive index of the glass fiber. When using a capillary of radius of 75 microns, it was obtained that m₂=1.58±0.05.

Thus, the following mechanism might occur during the preparation of the lasing films: Starting from the solution, irradiation with the intense preparation pulses first leads to evaporation of solvent while creating a solid deposit of rods on the capillary surface. Continued irradiation anneals this film and creates smooth films that show robust lasing behavior. A laser ablation process might take place where the film is deposited via the ablation of rods out of the solution. Based on the relatively small change in fluorescence seen from the films and from the original rod solutions, the preparation process essentially leaves the rods intact as separate entities and assists in annealing of the rods themselves and in forming a smooth film necessary for the intense lasing. This was corroborated by carrying out TEM measurements on rods that were redissolved from a pre-prepared laser film, showing that the rod architecture was generally conserved in this whole process (FIG. 5).

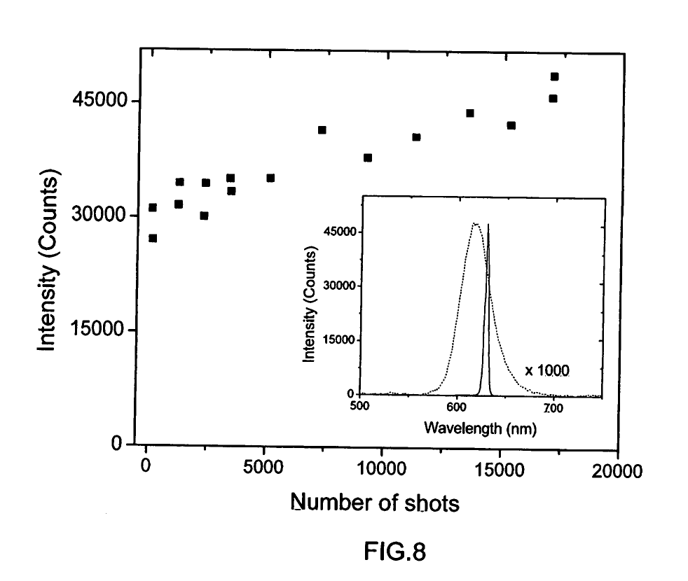

The stability of the prepared laser films was tested, by irradiating the prepared films with a train of pump pulses at energy slightly above the lasing threshold, at 0.04 mJ at a rate of 2 Hz. FIG. 8 shows the measurement results for of a film of 4 nm×14 nm CdSe/ZnS quantum rods in a cylindrical microcavity (pre-prepared as described above). The intensity at the lasing peak is plotted as a function of shot number showing an increase in intensity.

Inset in the figure shows a low-resolution spectra of the quantum rod PL (dashed line, multiplied by 1000) and lasing (solid line). Good lasing stability at ambient conditions was observed.

The method of the present invention can be extended to additional cavity architectures such as spherical, planar, on a chip etc. For example, the use of cylindrical lens illumination provides means for preparing larger areas for lasing.

The method could also be implemented to deposit and create lasing films in on-chip microcavities.

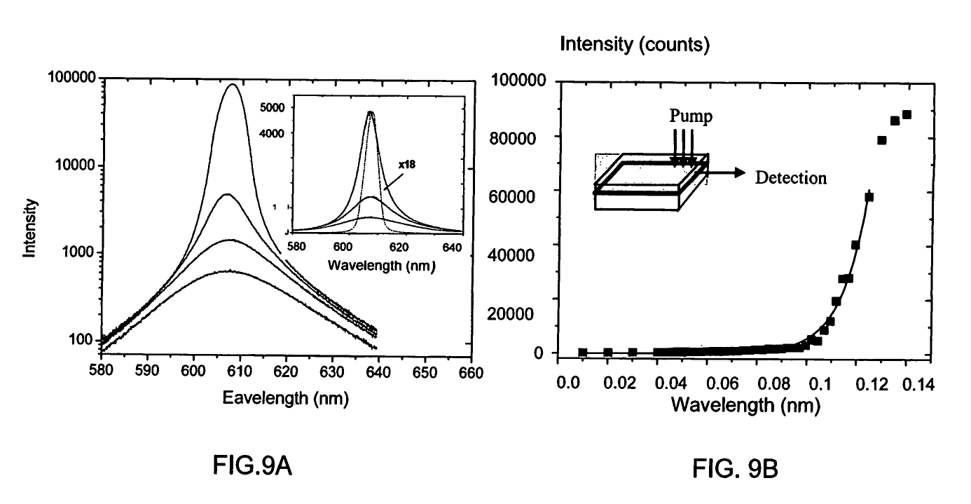

Another example of the preparation of a nanorods film on a planar surface is based on spin coating a quantum rods solution in toluene. In order to characterize the dependence of lasing efficiency on the dimension of the quantum rod, the variable stripe length method was carried out. In this geometry a variable excitation laser stripe was focused on a planar film of quantum rods on a glass substrate and the emission was collected from the edge of the planar film. The planar film acted as a waveguide structure enabling gain by Amplified Spontaneous Emission (ASE). FIG. 9A shows the emission spectra of quantum rods of 4.8 nm in diameter and 15 nm in length at different excitation stripe length. From bottom-up: 0.05 cm, 0.08 cm, 0.1 cm and 0.14 cm. The emission spectra shows narrowing as the stripe length is increased. The inset shows the emission spectra in linear scale where the stripe length for the first three traces as in the main figure and the dotted line is for a stripe length of 0.14 cm and the intensity is divided by 18, to clearly show the significant narrowing for optical gain in the films. FIG. 9B shows a plot of the ASE intensity at the emission peak versus the stripe length in linear scale. The theoretical fit gives a gain factor of 97 cm⁻¹. The inset displays schematically the experimental configuration in which an excitation laser beam is focused into a stripe on a planar film. The stripe length is adjusted by a moveable barrier while the spectrum is measured at each length.

The film was prepared by spin coating from a concentrated solution of quantum rods in toluene onto a glass cover slip. Typically, a 8 mm×8 mm glass cover slip that is pretreated with hexamethyldisilazane in order to improve the surface wetting, is spin coated at 600 RPM with a 40 microliters of a about 1×10^{31 5}M concentrated solution of quantum rods. This yielded smooth films of ˜100 microns in thickness and optical density in the range of 0.5 to 0.9.

Thus, the present invention provides for creating an optical device (e.g., laser cavity) formed by a nanocrystals film on a surface, which may be planar or not. The active region of the optical device is defined by the interface between the film and the surface. The film is created by processing the nanorods solution with electromagnetic radiation (e.g., laser radiation, e.g., a predetermined sequence of laser pulses) or by coating techniques.

Those skilled in the art will readily appreciate that various modifications and changes can be applied to the embodiments of the invention as hereinbefore described, without departing from its scope defined in and by the appended claims.

1. A method of producing a nanocrystals film for use in a solid state nanocrystals-based optical device, the method comprising processing a structure formed by a nanocrystals solution on a surface of a substrate, to thereby produce a film of said nanocrystals on said surface and create within an interface between said film and said surface a region capable of operating as an active region of the optical device.

2. The method of claim 1, wherein said processing comprises applying electromagnetic radiation to said structure.

3. The method of claim 1, wherein said electromagnetic radiation comprises at least one of the following: radiation by laser, and radiation by a lamp or a flash lamp.

4. (canceled)

5. The method of claim 2, wherein said electromagnetic radiation includes a predetermined sequence of light radiation pulses.

6. The method of claim 1, wherein said surface is selected from the inner surface of a substantially cylindrical microcavity, a waveguide or optical cavity structure on a chip, and a substantially planar surface.

7. The method of claim 5, wherein the substrate's surface is substantially planar.

8. The method of claim 5, wherein said surface is an inner surface of a substantially cylindrically shaped substrate.

9. The method of claim 1, wherein said nanocrystals have a shape selected from spheres, rods, tubes, wires and branched structures such as tripods and tetrapods.

10. The method of claim 1, wherein said nanocrystals are made of a semiconductor material, alloy of semiconductor materials or mixtures of semiconductor materials.

11. The method of claim 9, wherein the nanocrystals are made of a semiconductor material selected from Group II-VI semiconductors and alloys, Group III-V semiconductors and alloys, Group IV-VI semiconductors and alloys, Group IV semiconductors and alloys, combinations of the semiconductors in composite structures and core/shell structures of the above semiconductors.

12. The method of claim 10, wherein the nanocrystals are made from Group II-VI semiconductors and alloys.

13. The method of claim 10, wherein the nanocrystals are made in core/shell structures.

14. The method of claim 1, wherein said nanocrystals are in the form of rods.

15. The method of claim 13, wherein said processing comprises applying to said structure a sequence of laser pulses at an energy of about 1-300 mJ and a repetition rate of 1 Hz to several kHz for a period of several minutes.

16. The method of claim 1, wherein said processing comprises exposing the substantially planar surface holding the nanocrystals solution, to a coating technique.

17. An optical device, comprising a nanocrystals film on a surface of a substrate, an active region of said device being presented by an interface between said film and said surface, and being created by processing a solution of said nanocrystals while on said surface to thereby produce said film.

18. The device of claim 17, wherein said surface is a substantially planar surface.

19. The device of claim 17, wherein said surface is an inner surface of a substantially cylindrically shaped substrate.

20. The device of claim 17, wherein said surface is an inner surface of a substantially cylindrical microcavity, a waveguide or optical cavity structure on a chip.

21. The device of claim 17, wherein said nanocrystals have a shape selected from spheres, rods, branched structures such as tripods and tetrapods, tubes and wires.

22. The device of claim 17, wherein said nanocrystals are made of a semiconductor material, alloy of semiconductor materials or mixtures of semiconductor materials.

23. The device of claim 22, wherein the nanocrystals are made of a semiconductor material selected from Group II-VI semiconductors and alloys, Group III-V semiconductors and alloys, Group IV-VI semiconductors and alloys, Group IV semiconductors and alloys, combinations of the above semiconductors in composite structures and core/shell structures of the above semiconductors.

24. The device of claim 23, wherein the nanocrystals are made from Group II-VI semiconductors and alloys.

25. The device of claim 23, wherein the nanocrystals are made in core/shell structures.

26. The device of claim 17, operable as a laser device.

27. The device of claim 17, wherein the nanocrystals are CdSe/ZnS nanorods.

28. The device of claim 27 wherein said nanorods are core/shell structured.
